(19) United States
(12) Patent Application Publication
(10) Pub. No.: US 2022/0392818 A1
(43) Pub. Date: Dec. 8, 2022

(54) BOND FOOT SEALING FOR CHIP FRONTSIDE METALLIZATION

(71) Applicant: Infineon Technologies AG, Neubiberg (DE)

(72) Inventor: Carsten Ehlers, Monchengladbach (DE)

(21) Appl. No.: 17/368,303

(22) Filed: Jul. 6, 2021

Related U.S. Application Data
(60) Provisional application No. 63/208,288, filed on Jun. 8, 2021.

(51) Int. Cl. H01L 23/31; H01L 23/29; H01L 23/10; H01L 23/498

(52) U.S. Cl. CPC H01L 23/3142; H01L 23/293; H01L 23/10; H01L 23/49811; H01L 23/49822; H01L 23/49838; H01L 23/49866

(57) ABSTRACT

A semiconductor die is disclosed. The semiconductor die includes a semiconductor body, a metallization over part of the semiconductor body and including a noble metal at a top surface of the metallization, a bondwire having a foot bonded to the top surface of the metallization, and a sealing material covering the foot of the bondwire, the top surface of the metallization, and one or more areas outside the top surface of the metallization where oxide and/or hydroxide-groups would be present if exposed to air. The sealing material adheres to the foot of the bondwire and the one or more areas outside the top surface of the metallization where the oxide and/or hydroxide-groups would be present if exposed to air.

### TECHNICAL FIELD

The present application relates to bond foot sealing at the frontside metallization of semiconductor chips, in particular to bond foot sealing at frontside chip metallizations that include one or more noble metals.

### BACKGROUND

Increasing power cycling (power on/off) capability is an important requirement for automotive products such as inverters for EVs (electric vehicles). Some bare semiconductor dies (chips) used in inverter packages or modules have a front side metallization made of a noble metal such as Pd or PdAu. Usage of conventional processes such as Al wire bonds with a polyimide (Pl) bond foot sealing or usage of Cu wire bonds to increase the power cycling capability are not possible with such chips. Both conventional processes do not work on a chip surface with Pd or Au as the front side metallization. The process with Cu wires requires a thick Cu surface at the top of the front side metallization. The process with polyimide bond foot sealing requires a high oxygen content which oxidizes the surface to provide high adhesion to the chip frontside metallization, but only works well for frontside metallizations such as AlCu or AlSiCu but not noble metals such as Pd and PdAu.

A conventional polyimide bond foot sealing mechanism, illustrated in FIG. 1, does not work on semiconductor chips having a top layer made of a noble metal such as Pd or PdAu because the stable phase of these metals is pure metal. Noble metals do not build thin oxide or hydroxide layers in the presence of air. Accordingly, a conventional polyimide bond foot sealing material has no adhesion to the chip surface. FIG. 1 shows an adhesion mechanism between a polyimide-based sealing material and a non-noble metal chip frontside metallization such as AlCu. The Si—OH groups of the adhesion promoter of the polyimide-based polymer react with hydroxide- or oxide-groups of the non-noble metal chip metallization to build a strong chemical bond.

Simulation results show that without any adhesion to the chip surface, a polyimide bond foot sealing material has only a very small influence on power cycling capability. In other words, the effect of polyimide bond foot sealing on power cycling capability is negligible without any adhesion to the chip surface. A summary of the simulation results are provided in Table 1.

TABLE 1

| System | Energy Density [Mpa] | Lifetime |
|---|---|---|
| Without PI | 1.57 | 1 |
| With PI | 0.67 | 4.8 |
| With PI but Without Adhesion | 1.48 | 1.1 |

Power cycling of actual semiconductor chips having a noble metal such as Pd or PdAu as the frontside metallization shows similar behavior as seen in power cycling test results, as shown in FIG. 2. No increase in power cycling lifetime was observed by using a conventional polyimide bond foot sealing process as compared to no bond foot sealing at all. Further, observation from analysis of the samples shows no adhesion of the bond food sealing material on the chip noble metal surface. The entire bond foot sealing material remained only at the wire bond, with nothing left of the bond foot sealing material on the chip frontside noble metallization after analysis of the lift-off-failures.

As such, there is a need for an enhanced bond foot sealing technique for increasing power cycling reliability of semiconductor dies having a frontside noble metallization.

### SUMMARY

According to embodiments described herein, an enhanced bond foot sealing technique is provided for increasing power cycling reliability at the frontside noble metallization of semiconductor dies.

According to an embodiment of a semiconductor die, the semiconductor die comprises: a semiconductor body; a metallization over part of the semiconductor body and comprising a noble metal at a top surface of the metallization; a bondwire having a foot bonded to the top surface of the metallization; and a sealing material covering the foot of the bondwire, the top surface of the metallization, and one or more areas outside the top surface of the metallization where oxide and/or hydroxide-groups would be present if exposed to air, wherein the sealing material adheres to the foot of the bondwire and the one or more areas outside the top surface of the metallization where the oxide and/or hydroxide-groups would be present if exposed to air.

According to an embodiment of a power electronic circuit, the power converter circuit comprises: a plurality of semiconductor dies electrically connected to form an inverter or a converter, wherein each semiconductor die of the plurality of semiconductor dies comprises: a semiconductor body; a metallization over part of the semiconductor body and comprising a noble metal at a top surface of the metallization; a bondwire having a foot bonded to the top surface of the metallization; and a sealing material covering the foot of the bondwire, the top surface of the metallization, and one or more areas of the semiconductor die outside the top surface of the metallization where oxide and/or hydroxide-groups would be present if exposed to air, wherein the sealing material adheres to the foot of the bondwire and the one or more areas outside the top surface of the metallization where the oxide and/or hydroxide-groups would be present if exposed to air.

According to an embodiment of a semiconductor device, the semiconductor device comprises: a semiconductor body; a bond pad over part of the semiconductor body, the bond pad having a top surface layer that comprises one or more noble metals; a passivation laterally adjacent the top surface layer of the bond pad and delimiting a bonding area for the top surface layer of the bond pad; a bondwire having a foot bonded to the bonding area for the top surface layer of the bond pad; and a sealing material covering the foot of the bondwire, the bonding area for the top surface layer of the bond pad, and the passivation, wherein the sealing material adheres to the foot of the bondwire and the passivation.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates conventional bond foot sealing for non-noble chip metallizations such as AlCu.

FIG. 2 illustrates power cycling test results for power semiconductor chips having a noble chip metallization and conventional bond foot sealing.

FIGS. 3 and 4 illustrate an embodiment of semiconductor devices with an enhanced bond foot sealing structure, where FIG. 3 is a top plan view and FIG. 4 is a representative cross-sectional view.

FIG. 5 illustrates a partial cross-sectional view of a semiconductor device, showing the frontside metallization in more detail.

FIG. 6 illustrates a top plan view of an embodiment of a bond pad configuration.

FIG. 7 illustrates a cross-sectional view of another embodiment of a semiconductor device with an enhanced bond foot sealing structure.

FIG. 8 illustrates power cycling tests results for chips with an enhanced bond foot sealing structure, chips with a conventional bond foot sealing structure and chips with no bond foot sealing structure.

FIG. 9 illustrates a lift-off mechanism observed for the chips with the conventional bond foot sealing structure and the chips with no bond foot sealing structure, after the power cycling test summarized in FIG. 8.

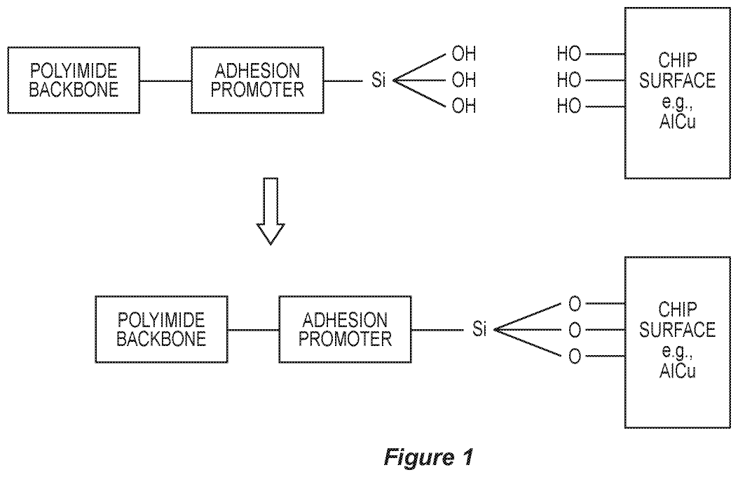

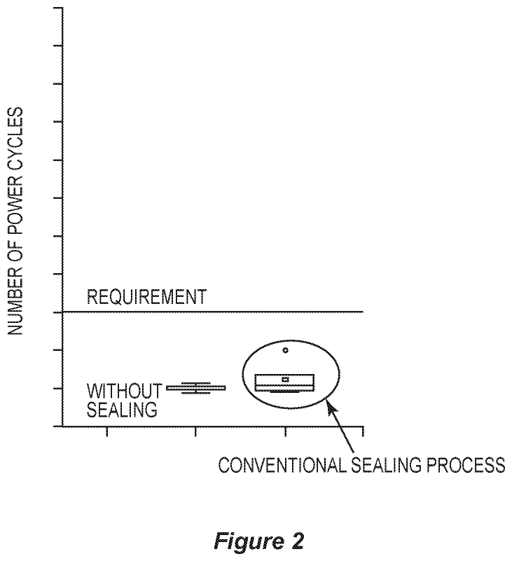

### DETAILED DESCRIPTION

The enhanced bond foot sealing technique described herein increases power cycling capability for semiconductor dies (chips) having a frontside metallization that comprises one or more noble metals such as palladium (Pd), gold (Au), palladium-gold (PdAu), etc. The semiconductor chips may be used in various power conversion applications such as in automotive products like inverters for electric vehicles (EVs). For example, a plurality of the semiconductor chips may be electrically connected to form a power electronic circuit such as an inverter or a converter. In general, the semiconductor chips have a frontside metallization that includes a noble metal top layer such as Pd, Au, PdAu, etc. The chips may be provided as bare dies or as packaged dies, e.g., attached to a substrate and sealed/molded but with accessible bond pads.

The power cycling capability of the semiconductor chips is increased with the enhanced sealing process described herein. The area coated by the sealing material (e.g., polyimide) is increased beyond the area of the frontside metallization, providing strong adhesion outside the chip frontside metallization to areas where oxide and/or hydroxide-groups would be present if exposed to air. For example, OH-groups may be present outside the noble metal top layer before an adhesion promoter reacts with the surfaces of the die. The adhesion promoter may cover the entire surface around the die pads, meaning there are no OH groups left. However, OH and/or O groups would be present at each of these (non-noble metal) surfaces in the presence of air. These surfaces therefore have different physicochemical properties compared to the noble metal top layer of the die, enabling stronger adhesion with the sealing material outside the region of the noble metal top layer.

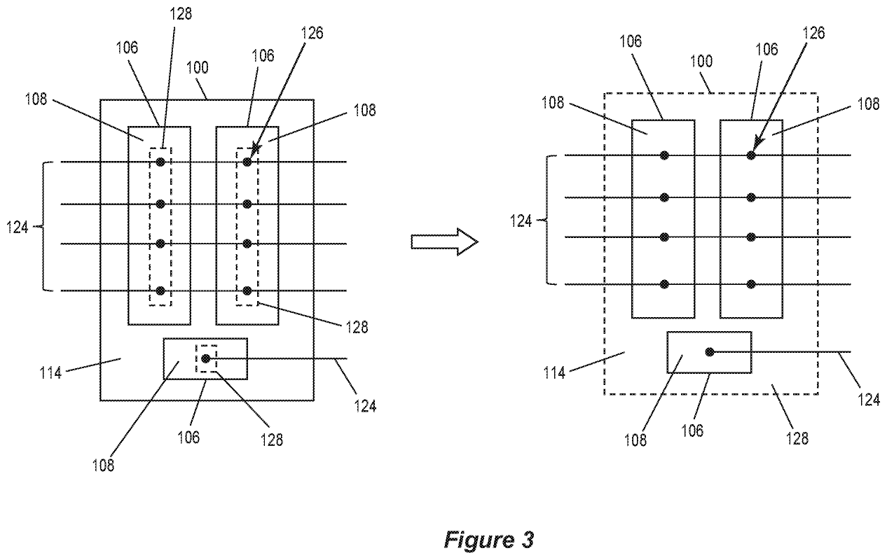

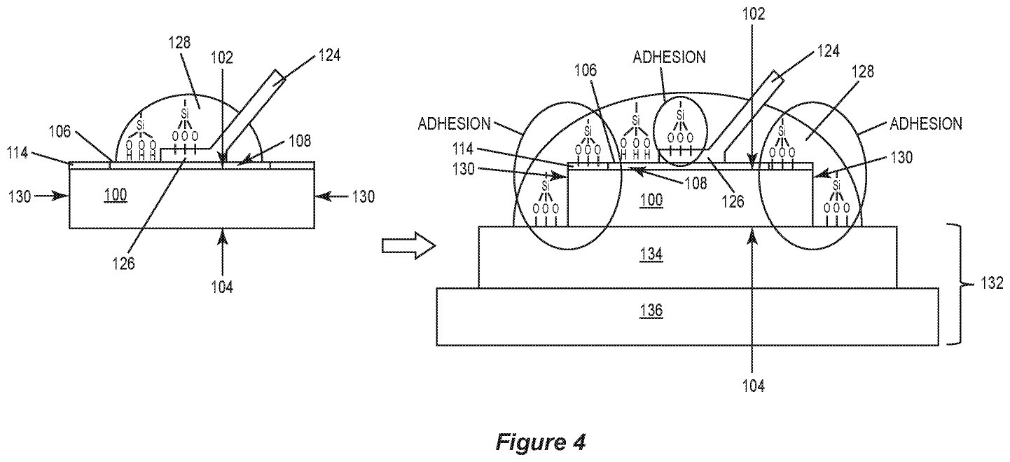

FIGS. 3 and 4 illustrate one embodiment of the enhanced sealing structure. FIG. 3 is a top plan view whereas FIG. 4 is a representative cross-sectional view.

The semiconductor chips shown in FIGS. 3 and 4 include a semiconductor body 100 that may comprise any type of semiconductor material such as Si, SiC, GaN, etc. The semiconductor body 100 may include a base semiconductor and one or more epitaxial layers grown on the base semiconductor.

The semiconductor body 100 may include 10s, 100s, 1000s or even more device cells that are electrically connected in parallel to form a device such as a transistor and/or a diode. For example, the semiconductor body 100 may include a plurality of transistor cells electrically coupled in parallel to form a power transistor and/or a plurality of diode cells electrically coupled in parallel to form a power diode. Transistor cells may share a source or emitter connection, a drain or collector connection, and a gate connection. The resulting transistor and/or diode may be a vertical device in that the primary current flow direction is between front and back main surfaces 102, 104 of the semiconductor body 100. The device instead may be a lateral device in that the primary current flow direction is along the front main surface 102 of the semiconductor body 100. In the case of a power transistor, the device may be a power MOSFET (metal-oxide-semiconductor field-effect transistor), an IGBT (insulated gate bipolar transistor), a HEMT (high-electron mobility transistor), etc. An illustration of the device cells is omitted from FIGS. 3 and 4 to emphasize the layers formed over the semiconductor body 100.

In each case, a frontside metallization 106 is formed over part of the front main surface 102 of the semiconductor body 100. The frontside metallization 106 includes a top surface layer 108 that comprises one or more noble metals such as Pd, Au, PdAu, etc.

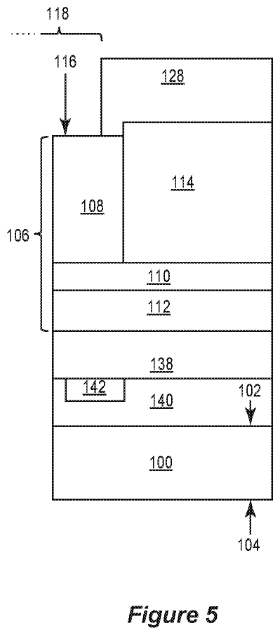

FIG. 5 illustrates a partial cross-sectional view of the semiconductor device, showing the frontside metallization 106 in more detail. The frontside metallization 106 is the uppermost wiring structure for the semiconductor device. The frontside metallization 106 may include a metallization layer 110 with the top surface layer 108 formed over the metallization layer 110. The metallization layer 110 functions as a wiring structure, and the top surface layer 108 comprises one or more noble metals such as Pd, Au, PdAu, etc. One or more additional metal or metal alloy layers may be interposed between the top surface layer 108 and the underlying metallization layer 110. For example, a NiP layer may be interposed between the top surface layer 108 and the underlying metallization layer 110.

The top surface layer 108 of the frontside metallization 106 may be structured to form one or more bond pads that provide contact points for bond wire connections to the semiconductor device 100. For example, in the case of a vertical power transistor, the top surface layer 108 may be structured to include source/emitter and gate contact pads whereas the drain/collector pad may be formed at the back main surface 104 of the semiconductor body 100. In the case of a lateral power transistor, the top surface layer 108 may be structured to include all contact pads for the semiconductor device. The metallization layer 110 below the top surface layer 108 may be structured to ensure proper isolation between different potentials at the respective contact pads.

The metallization layer 110 below the top surface layer 108 may comprise an aluminum compound. For example, the metallization layer 110 may comprise AlCu or AlSiCu. Other metal systems may be used for the metallization layer 110, e.g., Cu, and one or more additional metallization layers 112 may be formed below and in contact with the metallization layer 110. For example, in the case of AlCu or AlSiCu as the metallization layer 110, the one or more additional metallization layers 112 may include TiN (titanium nitride) and/or Ti (titanium). In general, the frontside metallization 106 may include a plurality of metallization layers to enhance electromigration robustness, increase adhesion, improve thermal stability, reduce sheet resistance, etc.

Only part of the top surface layer 108 and metallization layer 110 are shown in FIG. 5 to emphasize the interface between the edge of the top surface layer 108 and the edge of a passivation 114 formed over the metallization layer 110. The passivation 114 is disposed over the metallization layer 110 and is laterally adjacent to the top surface layer 108. The passivation 114 may or may not extend the top surface 116 of the top surface layer 108 that faces away from the semiconductor body 100. In either case, at least part of the surface 116 of the top surface layer 108 that faces away from the semiconductor body 100 is uncovered by the passivation 114. Accordingly, the passivation 114 delimits at least one bonding area 118 for the top surface layer 108 of the frontside metallization 106. Each bonding area 118 delimited by the passivation 114 is part of a separate bond pad formed in the top surface layer 108 of the frontside metallization 106.

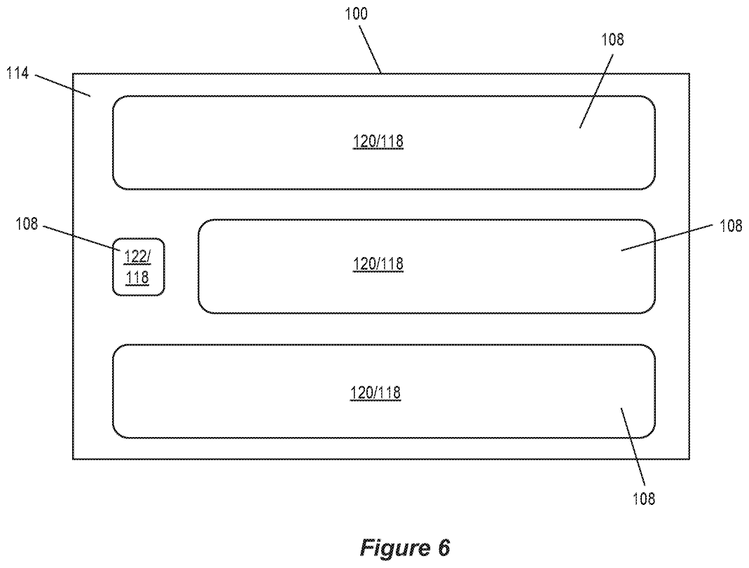

FIG. 6 illustrates a top plan view of an embodiment where the top surface layer 108 of the frontside metallization 106 is segmented into a plurality of bond pads 120, 122. For example, in the case of a power transistor, first bond pads 120 may be for source or emitter connections and a second bond pad 122 may be for a control signal connection. The source pads 120 are electrically connected to the source of each transistor cell that forms the power transistor in the semiconductor body 100, and the gate pad 122 is electrically connected to the gate of each power transistor cell. In each case, part or all of the surface 116 of the top surface layer 108 for each bond pad 120, 122 is uncovered by the passivation 114 to enable wire bonding to the bond pads 120, 122.

Returning to FIGS. 3 and 4, a (e.g., Al) bondwire 124 is shown bonded to the top surface layer 108 of the frontside metallization 106. The bonding area 118 for the top surface layer 108 and to which the bondwire 124 is attached forms part of a bond pad such as a source/emitter pad or gate pad of a power transistor or an anode pad or cathode pad of a power diode. An exemplary pad configuration is shown in FIG. 6, but this is just an example.

The bondwire 124 bonded to the top surface layer 108 of the frontside metallization 106 may be a ball or wedge bond. That is, the foot (proximal end) 126 of the bondwire 124 may be ball-shaped or wedge-shaped. More than one bondwire 124 may be bonded to the same die pad, e.g., in the case of a source/emitter pad 120. In the case of a power transistor device, the foot 126 of an additional bondwire 124 may be bonded to the bonding area 118 for the top surface layer 108 of the frontside metallization 106 that forms a gate pad 122. The additional bondwire 124 and gate pad 122 are not visible in the cross-sectional views of FIGS. 4 and 5.

To the left of the horizontal arrow in FIGS. 3 and 4 shows a bond foot sealing material 128 applied only on the top surface layer 108 of the frontside metallization 106 whereas to the right of the horizontal arrow in FIGS. 3 and 4 shows the bond foot sealing material 128 also applied to one or more areas outside the top surface layer 108 of the frontside metallization 106 and where oxide and/or hydroxide-groups would be present if exposed to air. For example, the sealing material 128 may cover the foot 126 of the bondwire 124, the bonding area 118 for the top surface layer 108 of each bond pad 120/122, and the passivation 114. In this case, the sealing material 128 adheres to both the foot 126 of the bondwire 124 and the passivation 114. As explained above, and in the case of a power transistor, multiple bond pads 120, 122 may be formed in the top surface layer 108 of the frontside metallization 106, e.g., as shown in FIG. 6. In this case, the sealing material 128 covers at least the foot 126 of each bondwire 124, the bonding area 118 for the top surface layer 108 of each bond pad 120/122, and the passivation 114. The sealing material 128 is illustrated by dashed rectangles in FIG. 3 to provide an unobstructed view of the underlying top surface layer 108 of the frontside metallization 106, and is not shown in FIG. 6 to provide an unobstructed view of the exemplary bond pad arrangement.

The sealing material 128 may also extend onto and adhere to the edge 130 of the semiconductor body 100 which extends between the front main surface 102 and the back main surface 104 of the semiconductor body 100, e.g., as shown to the right of the horizontal arrow in FIG. 4. The edge 130 of the semiconductor body 100 delimits where the semiconductor die was singulated from other dies fabricated from the same semiconductor wafer.

In some cases, the semiconductor device may be at least partly packaged in that the back main surface 104 of the semiconductor body 100 may be attached to a substrate 132 such as a leadframe, a DCB (direct copper bonded) substrate, an AMB (active metal brazed) substrate, an IMS (insulated metal substrate), etc. The substrate 132 may have a patterned metallized layer 134 on an insulating substrate 136 such as a ceramic, and to which the semiconductor body 100 is attached. The sealing material 128 may extend onto and adhere to the metallization 134 of the substrate 132, e.g., as shown to the right of the horizontal arrow in FIG. 4. In one embodiment, the metallization 134 of the substrate 132 comprises Cu.

In the area of the top surface layer 108 of the frontside metallization 106, little to no adhesion occurs between the sealing material 128 and the top surface layer 108 since the top surface layer 108 comprises one or more noble metals such as Pd, Au, PdAu, etc. With the enhanced sealing technique described herein, the sealing material 128 extends onto one or more areas outside the top surface layer 108 of the frontside metallization 106 where oxide and/or hydroxide-groups would be present if exposed to air. For example, the sealing material 128 may extend onto the passivation 114 that laterally adjoins the top surface layer 108 of the frontside metallization 106. The sealing material 128 also may extend onto the edge 130 of the die semiconductor body 100. The sealing material 128 may further extend onto a non-noble (e.g., Cu) metallization 134 of a substrate 132 to which the semiconductor die is attached. In each case, the sealing material 128 adheres to the foot 126 of the bondwire 124 and at least one area outside the top surface layer 108 of the frontside metallization 106 where oxide and/or hydroxide-groups would be present if exposed to air.

The adhesion regions are indicated to the right of the horizontal arrow in FIG. 4 by ovals. In this example, the sealing material 128 is polyimide. During the bond foot sealing process, Si—OH groups of an adhesion promoter included with the polyimide-based polymer react with hydroxide- and/or oxide-groups of each non-noble surface contacted by the sealing material 128 to build a strong chemical bond. The sealing material 128 may comprise polyimide, polyacrylate, polybenzoxazole (PBO), cyclotene, thermoplastic adhesive based on polyurethane, epoxide, silicone, polyamide, etc., or epoxy.

FIG. 5 shows the frontside metallization 106 as the only wiring layer/structure formed over the semiconductor body 100. However, one or more additional wiring layers may be formed between the frontside metallization 106 and the semiconductor body 100 and separated from one another by an ILD (interlayer dielectric) 138. The lowermost ILD 138 provides separation from the overlying wiring layers/structures and the semiconductor body 100. Each ILD 138 may comprise a single insulating layer or two or more different insulating layers such as TEOS (tetraethyl orthosilicate), BPSG (borophosphosilicate glass), etc.

In the case of a planar gate device, a gate oxide 140 is formed on the front main surface 102 of the semiconductor body 100 and a gate electrode 142 is separated from the semiconductor body 100 by the gate oxide 140. For a trench gate device, the gate electrode 142 would be disposed in a trench formed in the semiconductor body 100 and the gate oxide 140 would line the sidewalls and bottom of the trench to separate the gate electrode 142 from the semiconductor body 100. As explained above, the semiconductor body 100 may include 10s, 100s, 1000s or even more planar gate or trench gate transistor cells that are electrically connected in parallel to form a transistor such as a power MOSFET, IGBT, HEMT, etc.

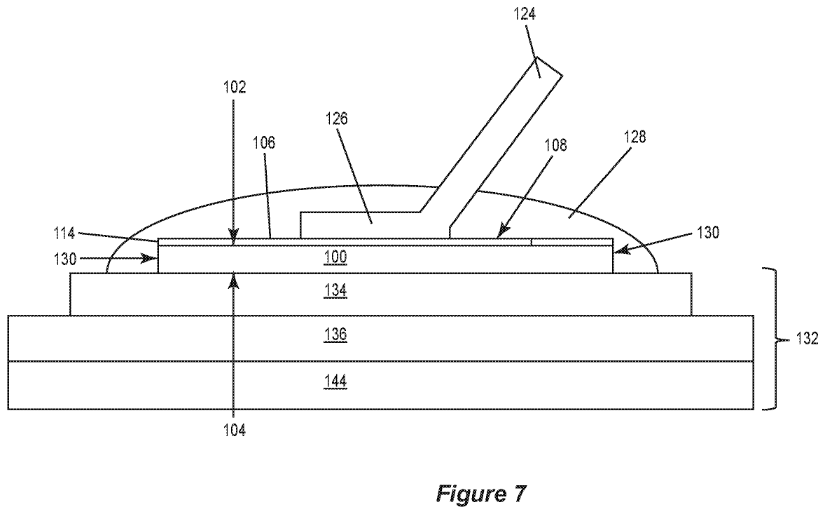

FIG. 7 illustrates a cross-sectional view of another embodiment of a semiconductor device that includes the enhanced sealing structure. The embodiment illustrated in FIG. 7 is similar to the embodiment illustrated to the right of the horizontal arrow in FIG. 4, wherein the substrate 132 in FIG. 7 includes both front and back side metallizations 134, 144 such as Cu on a ceramic body 136.

In each case, the power cycling capability for the semiconductor chips shown in FIGS. 3 through 7 is increased by extending the bond foot sealing material 128 onto one or more areas outside the top surface layer 108 of the frontside metallization 106 where oxide and/or hydroxide-groups would be present if exposed to air.

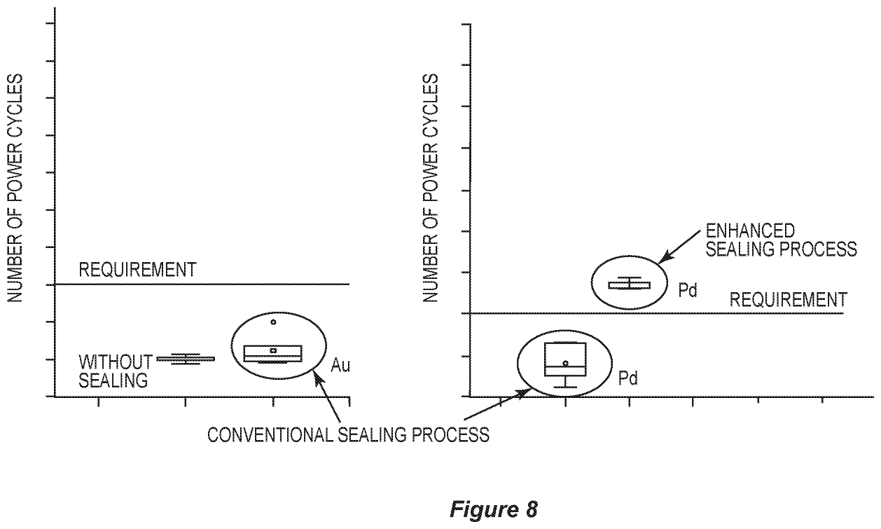

FIG. 8 illustrates results from different power cycling tests implemented with chips that may be used as inverters for EV automotive applications, for example. The semiconductor chips produced using the enhanced sealing process described herein and illustrated in the right hand side of FIGS. 3-4 and in FIGS. 5-7 exceed the stated power cycling requirement.

The samples without any bond foot sealing and with the conventional bond foot sealing process illustrated in the left hand side of FIGS. 3 and 4 do not meet the power cycling requirement. The samples with the conventional bond foot sealing process included both Au frontside metallization and Pd frontside metallization. The chips produced using the enhanced sealing process also used Pd as the top surface layer 108 of the frontside metallization 106.

It was observed that for the samples without bond foot sealing (labelled “without sealing” in FIG. 8) and the samples produced with the conventional bond foot sealing process (labelled “conventional sealing process” in FIG. 8), the main failure mechanism was a lift-off mechanism whereby the foot of the bondwire lifts off the frontside metallization.

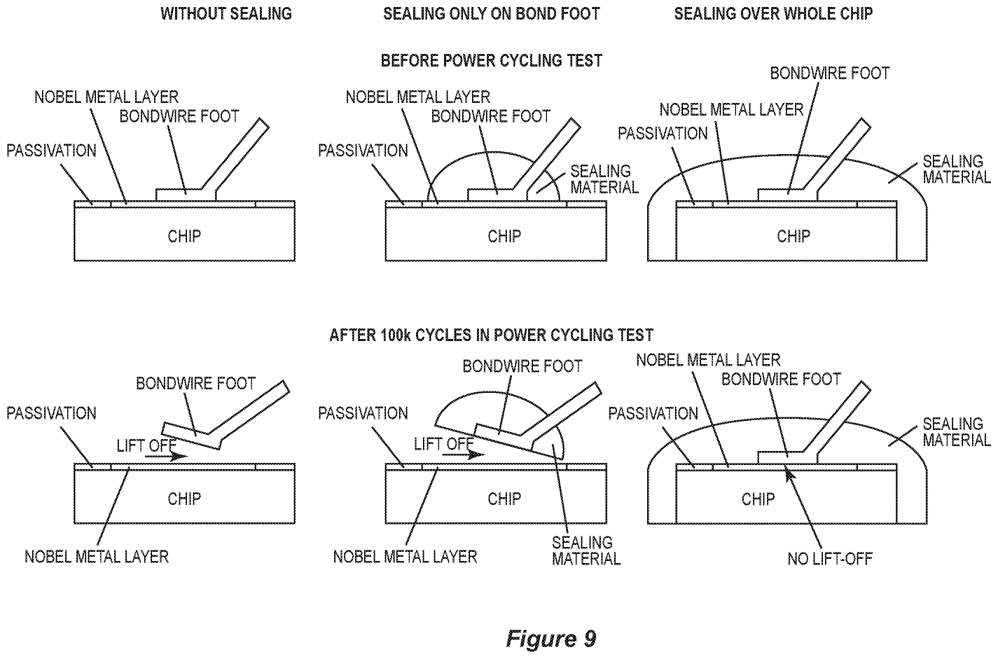

The lift-off mechanism is illustrated in the left (“without sealing”) and middle (“sealing only on bond foot”) part of FIG. 9. Especially the samples produced with the conventional bond foot sealing process show a complete delamination of the sealing material from the top of the noble metal layer (Au or Pd in this case). The chips produced using the enhanced sealing process had no lift-off failure at the same number of power on cycles, as indicated in the right hand (“sealing over whole chip”) part of FIG. 9.

Although the present disclosure is not so limited, the following numbered examples demonstrate one or more aspects of the disclosure.

Example 1. A semiconductor die, comprising: a semiconductor body; a metallization over part of the semiconductor body and comprising a noble metal; a bondwire having a foot bonded to the metallization; and a sealing material covering the foot of the bondwire, the metallization, and one or more areas outside the metallization where oxide and/or hydroxide-groups would be present if exposed to air, wherein the sealing material adheres to the foot of the bondwire and the one or more areas outside the metallization where the oxide and/or hydroxide-groups would be present if exposed to air.

Example 6. The semiconductor die of any of examples 1 through 5, wherein the sealing material extends onto and adheres to a chip passivation that laterally adjoins the metallization.

Example 7. The semiconductor die of any of examples 1 through 6, wherein the semiconductor die is attached to a substrate, and wherein the sealing material extends onto and adheres to a metallization of the substrate.

Example 8. The semiconductor die of example 7, wherein the metallization of the substrate comprises Cu.

Example 9. The semiconductor die of any of examples 1 through 8, wherein the semiconductor die comprises a power transistor and/or a power diode.

Example 11. A semiconductor die, comprising: a semiconductor body; a metallization over part of the semiconductor body and comprising a noble metal at a top surface of the metallization; a bondwire having a foot bonded to the top surface of the metallization; and a sealing material covering the foot of the bondwire, the top surface of the metallization, and one or more areas outside the top surface of the metallization where oxide and/or hydroxide-groups would be present if exposed to air, wherein the sealing material adheres to the foot of the bondwire and the one or more areas outside the top surface of the metallization where the oxide and/or hydroxide-groups would be present if exposed to air.

Example 12. The semiconductor die of example 11, wherein the semiconductor body comprises SiC.

Example 13. The semiconductor die of example 11 or 12, wherein the noble metal comprises Pd.

Example 14. The semiconductor die of example 11 or 12, wherein the noble metal comprises PdAu.

Example 15. The semiconductor die of any of examples 11 through 14, wherein the sealing material comprises polyimide.

Example 16. The semiconductor die of any of examples 11 through 15, wherein the sealing material extends onto and adheres to a chip passivation that laterally adjoins the top surface of the metallization.

Example 17. The semiconductor die of any of examples 1 through 16, wherein the semiconductor die is attached to a substrate, and wherein the sealing material extends onto and adheres to a metallization of the substrate.

Example 18. The semiconductor die of example 17, wherein the metallization of the substrate comprises Cu.

Example 19. The semiconductor die of any of examples 11 through 18, wherein the semiconductor die comprises a power transistor and/or a power diode.

Example 20. A power electronic circuit, comprising: a plurality of semiconductor dies electrically connected to form an inverter or a converter, wherein each semiconductor die of the plurality of semiconductor dies comprises: a semiconductor body; a metallization over part of the semiconductor body and comprising a noble metal at a top surface of the metallization; a bondwire having a foot bonded to the top surface of the metallization; and a sealing material covering the foot of the bondwire, the top surface of the metallization, and one or more areas of the semiconductor die outside the top surface of the metallization where oxide and/or hydroxide-groups would be present if exposed to air, wherein the sealing material adheres to the foot of the bondwire and the one or more areas outside the top surface of the metallization where the oxide and/or hydroxide-groups would be present if exposed to air.

Example 21. A semiconductor device, comprising: a semiconductor body; a bond pad over part of the semiconductor body, the bond pad having a top surface layer that comprises one or more noble metals; a passivation laterally adjacent the top surface layer of the bond pad and delimiting a bonding area for the top surface layer of the bond pad; a bondwire having a foot bonded to the bonding area for the top surface layer of the bond pad; and a sealing material covering the foot of the bondwire, the bonding area for the top surface layer of the bond pad, and the passivation, wherein the sealing material adheres to the foot of the bondwire and the passivation.

Example 22. The semiconductor device of example 21, wherein the semiconductor body has a first main surface, a second main surface opposite the first main surface, and an edge extending between the first main surface and the second main surface, wherein the bond pad is disposed over part of the first main surface of the semiconductor body, and wherein the sealing material extends onto and adheres to the edge of the semiconductor body.

Example 23. The semiconductor device of example 21 or 22, wherein the semiconductor body comprises SiC.

Example 24. The semiconductor device of any of examples 21 through 23, wherein the top surface of the bond pad comprises Pd, Au or PdAu.

Example 25. The semiconductor device of any of examples 21 through 24, wherein the sealing material is selected from the group consisting of polyimide, polyacrylate, polybenzoxazole (PBO), cyclotene, thermoplastic adhesive, and epoxy.

Example 26. The semiconductor device of any of examples 21 through 25, wherein the semiconductor body is attached to a substrate at an opposite side of the semiconductor body as the bond pad, and wherein the sealing material extends onto and adheres to a metallization of the substrate.

Example 27. The semiconductor device of example 26, wherein the metallization of the substrate comprises Cu.

Example 28. The semiconductor device of any of examples 21 through 27, wherein a power transistor and/or a power diode are formed in the semiconductor body.

Example 29. The semiconductor device of any of examples 21 through 28, wherein a power transistor is formed in the semiconductor body, and wherein the bond pad is a source pad electrically connected to a source of the power transistor.

Example 30. The semiconductor device of example 29, further comprising: a gate pad laterally spaced apart from the source pad and having a top surface layer that comprises one or more noble metals, the passivation delimiting a bonding area for the top surface layer of the source pad; and an additional bondwire having a foot bonded to the bonding area for the top surface layer of the gate pad, wherein the sealing material covers the foot of the additional bondwire and the bonding area for the top surface layer of the gate pad, wherein the sealing material adheres to the foot of the additional bondwire and to the part of the passivation that delimits the bonding area for the top surface layer of the source pad.

Terms such as “first”, “second”, and the like, are used to describe various elements, regions, sections, etc. and are not intended to be limiting. Like terms refer to like elements throughout the description.

As used herein, the terms “having”, “containing”, “including”, “comprising” and the like are open-ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A semiconductor die, comprising:
a semiconductor body;
a metallization over part of the semiconductor body and comprising a noble metal at a top surface of the metallization;
a bondwire having a foot bonded to the top surface of the metallization; and
a sealing material covering the foot of the bondwire, the top surface of the metallization, and one or more areas outside the top surface of the metallization where oxide and/or hydroxide-groups would be present if exposed to air,
wherein the sealing material adheres to the foot of the bondwire and the one or more areas outside the top surface of the metallization where the oxide and/or hydroxide-groups would be present if exposed to air.

2. The semiconductor die of claim 1, wherein the noble metal comprises Pd, Au or PdAu.

3. The semiconductor die of claim 1, wherein the sealing material comprises polyimide.

4. The semiconductor die of claim 1, wherein the sealing material extends onto and adheres to a chip passivation that laterally adjoins the top surface of the metallization.

5. The semiconductor die of claim 1, wherein the semiconductor die is attached to a substrate, and wherein the sealing material extends onto and adheres to a metallization of the substrate.

6. The semiconductor die of claim 5, wherein the metallization of the substrate comprises Cu.

7. The semiconductor die of claim 1, wherein the semiconductor die comprises a power transistor and/or a power diode.

8. A power electronic circuit, comprising:
a plurality of semiconductor dies electrically connected to form an inverter or a converter,
wherein each semiconductor die of the plurality of semiconductor dies comprises:
a semiconductor body;
a metallization over part of the semiconductor body and comprising a noble metal at a top surface of the metallization;
a bondwire having a foot bonded to the top surface of the metallization; and
a sealing material covering the foot of the bondwire, the top surface of the metallization, and one or more areas of the semiconductor die outside the top surface of the metallization where oxide and/or hydroxide-groups would be present if exposed to air,
wherein the sealing material adheres to the foot of the bondwire and the one or more areas outside the top surface of the metallization where the oxide and/or hydroxide-groups would be present if exposed to air.

9. A semiconductor device, comprising:
a semiconductor body;
a bond pad over part of the semiconductor body, the bond pad having a top surface layer that comprises one or more noble metals;
a passivation laterally adjacent the top surface layer of the bond pad and delimiting a bonding area for the top surface layer of the bond pad;
a bondwire having a foot bonded to the bonding area for the top surface layer of the bond pad; and
a sealing material covering the foot of the bondwire, the bonding area for the top surface layer of the bond pad, and the passivation,
wherein the sealing material adheres to the foot of the bondwire and the passivation.

10. The semiconductor device of claim 9, wherein the semiconductor body has a first main surface, a second main surface opposite the first main surface, and an edge extending between the first main surface and the second main surface, wherein the bond pad is disposed over part of the first main surface of the semiconductor body, and wherein the sealing material extends onto and adheres to the edge of the semiconductor body.

11. The semiconductor device of claim 9, wherein the top surface of the bond pad comprises Pd, Au or PdAu.

12. The semiconductor device of claim 9, wherein the sealing material is selected from the group consisting of polyimide, polyacrylate, polybenzoxazole (PBO), cyclotene, thermoplastic adhesive, and epoxy.

13. The semiconductor device of claim 9, wherein the semiconductor body is attached to a substrate at an opposite side of the semiconductor body as the bond pad, and wherein the sealing material extends onto and adheres to a metallization of the substrate.

14. The semiconductor device of claim 13, wherein the metallization of the substrate comprises Cu.

15. The semiconductor device of claim 9, wherein a power transistor and/or a power diode are formed in the semiconductor body.

16. The semiconductor device of claim 9, wherein a power transistor is formed in the semiconductor body, and wherein the bond pad is a source pad electrically connected to a source of the power transistor.

17. The semiconductor device of claim 16, further comprising:
a gate pad laterally spaced apart from the source pad and having a top surface layer that comprises one or more noble metals, the passivation delimiting a bonding area for the top surface layer of the source pad; and
an additional bondwire having a foot bonded to the bonding area for the top surface layer of the gate pad,
wherein the sealing material covers the foot of the additional bondwire and the bonding area for the top surface layer of the gate pad,
wherein the sealing material adheres to the foot of the additional bondwire and to the part of the passivation that delimits the bonding area for the top surface layer of the source pad.
